(19) United States
(12) Patent Application Publication
(10) Pub. No.: US 2004/0009674 A1
(43) Pub. Date: Jan. 15, 2004

(54) Method for forming a filling film and method for forming shallow trench isolation of a semiconductor device using the same

(76) Inventors: Jong-Won Lee, Seongnam-Si (KR); Bo-Un Yoon, Gyeonggi-Do (KR); Jae-Kwang Choi, Nam-Gu (KR)

Correspondence Address: VOLENTINE FRANCOS, P.L.L.C., Suite 150, 12200 Sunrise Valley Drive, Reston, VA, 20191, US

(21) Appl. No.: 10/448,297

(22) Filed: May 30, 2003

(30) Foreign Application Priority Data
Jul. 9, 2002 (KR) 2002-39809

(51) Int. Cl. H01L 21/76

(52) U.S. Cl. 438/694; 438/424; 438/692; 438/697

(57) ABSTRACT

A method for forming a filling film having an even surface and a method for forming a trench isolation using a polishing process. After a substrate having stepped portions thereon is provided, a film is formed on the substrate to cover the stepped portions of the substrate. The edge of the stepped portion of the film is processed to have a round shape, and then the film including the round shaped edge portion is chemical-mechanically polished to form the filling film having an even surface. Before the film is polished, the film to be polished is processed to have the round shape, thereby increasing the polishing rate of the film.

### BACKGROUND OF THE INVENTION

1. Field of the Invention

The present invention relates to a method for forming a filling film and a method for forming a shallow trench isolation of a semiconductor device using the same, and more particularly, to a method for forming a filling film having an even surface by polishing and a method for forming a shallow trench isolation of a semiconductor device using the same.

A claim of priority is made to Korean Application No. 2002-39809 filed on Jul. 9, 2002, the entirety of which is incorporated herein by reference.

2. Description of the Related Art

Generally, an isolation structure of a semiconductor device can be accomplished through a thermal field oxidation process such as a local oxidation of silicon (LOCOS) process. In the LOCOS process for forming the isolation structure, after an oxide film and a nitride film are successively formed on a silicon substrate, the nitride film is patterned. Then, the substrate is selectively oxidized using the patterned nitride film as an anti-oxidation mask such that a field oxide film is formed on the substrate. According to the LOCOS process, however, bird's beaks may occur at both end portions of the field oxide film because oxygen ions permeate from under the nitride film used as the mask into the lateral portion of the oxide film during the selective oxidation of the substrate. Hence, the area of the active region of the substrate may decrease and the field oxide film may extend to the active region by the lengths of the bird's beaks.

Therefore, shallow trench isolation (STI) structures have been used for a very large scale integration semiconductor devices. In the process for the shallow trench isolation, after a trench is formed in a substrate by etching the substrate, an oxide film is deposited in the trench to fill the trench. Then, the oxide film is etched through an etch back process or a chemical-mechanical polishing process such that a field oxide film is formed in the trench.

One example of a conventional method for forming a trench isolation is disclosed in U.S. Pat. No. 6,015,757 (issued to Chia-Shiung Tsai et al.). According to the method of the above-mentioned U.S. Patent, after trenches are formed in a substrate and the trenches are filled with a burying material, the burying material is selectively etched and polished by a CMP process.

FIGS. 1A to 1D are cross-sectional views illustrating a conventional method for forming a shallow trench isolation. Referring to FIG. 1A, after a native oxide film 12 is formed on a silicon substrate 10, a nitride film 14 is formed on the native oxide film 12. The nitride film 14 serves as a polishing stop layer during a subsequent chemical-mechanical polishing (CMP) process, and also serves as a mark mask for forming a trench. Silicon oxy-nitride is deposited on the nitride film 14 to form an anti-reflection layer (not shown), and then a photolithography process is executed with reference to the substrate 10, in order to define an active region and a field region on the substrate 10.

Referring to FIG. 1B, portions of the nitride film 14 and the native oxide film 12 in the field region of the substrate 10 are successively etched to form nitride film patterns 14a and oxide film patterns 12a. Then, trenches 16a and 16b are formed in exposed portions of the substrate 10 between the patterns 14a and 12a. In general, the trenches 16a formed in a cell region (A) of the substrate 10 have very narrow widths while the trenches 16a in a peripheral region (B) of the substrate 10 are formed to have relatively wide widths. In addition, the trenches 16a in the cell region (A) are disposed to have very minute intervals therebetween, and the trenches 16b in the peripheral region (B) are positioned to have relatively large intervals therebetween.

Referring to FIG. 1C, an oxide film 20 in formed on the substrate 10 to fill the trenches 16a and 16b. At that time, the oxide film 20 is formed through a high density plasma chemical vapor deposition (HDP-CVD) process or a plasma enhanced chemical vapor deposition (PECVD) such that the oxide film 20 is coated in the trenches 16a and 16b without voids therein.

Referring to FIG. 1D, the oxide film 20 is polished by a CMP process until the nitride film patterns 14a are exposed. Thus, a field oxide film 22 is formed in the trenches 16a and 16b. Then, the nitride film patterns 14a are removed.

The CMP process is generally performed using a slurry that selectively removes the oxide film 20. By using the slurry that selectively removes the oxide film 20, the nitride film patterns 14a are hardly polished during the CMP process. When the oxide film 20 is polished until all the nitride film patterns 14a are exposed, the nitride film patterns 14a have nearly uniform thickness on the whole surface of the substrate 10 after the CMP process is completed. Hence, process failures caused by an over-etching process for removing the nitride film patterns 14a can be reduced, because an over-etching process to completely remove the nitride film patterns 14a is not needed. In addition, the field oxide film 22 in the trenches 16a and 16b has a uniform thickness.

However, in the case of an oxide film having stepped portions, the removing rate of the oxide film during a CMP process that uses a slurry to selectively remove the oxide film is very slow during the initial step of the CMP process. That is, when the oxide film including the stepped portions is polished with the slurry, the removing rate of the oxide film is very low during the initial processing time (concretely, about 30 to 60 seconds) from the start of the CMP process, and then the removing rate of the oxide film is rapidly increased beginning from a predetermined time after about 30 to 60 seconds from the start of the CMP process. Thus, the entire processing time of the CMP process may increase because the removing rate of the oxide film is very slow during the initial step of the CMP process. As a result, the throughput of the polishing process may decrease while the cost for manufacturing a semiconductor device may increase.

### SUMMARY OF THE INVENTION

The present invention is therefore directed to a method of forming a filling film which substantially overcomes one or more of the problems due to the limitations and disadvantages of the background art.

To solve the afore-mentioned problems, it is a first object of the present invention to provide a method for forming a filling film on a substrate having stepped portions formed thereon.

It is a second object of the present invention to provide a method for forming a trench isolation.

In order to achieve the above and other objects, there is provided a method for forming a filling film. On a substrate having stepped portions, a film is formed on the substrate to cover the stepped portions. An edge of a stepped portion of the film formed in accordance with the stepped portions of the substrate is processed to have a round shape and then the film is chemical-mechanically polished to have an even surface.

In order to achieve the above and other objects, there is also provided a method for forming a trench isolation. After forming a polishing stop layer on a substrate, portions of the polishing stop layer and the substrate are successively etched to form trenches in the substrate. An oxide film is formed so as to cover the trenches. Then, an edge of a stepped portion of the oxide film formed in accordance with formations of the trenches is processed to have a round shape, and the oxide film including the round shaped edge is chemical-mechanically polished to expose the polishing stop layer. In this case, a slurry used for polishing the oxide film can be directly combined with dangling bonds in the surface of the oxide film, to remove the oxide film. Also, the slurry used for polishing the oxide film can selectively remove the oxide film.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention and wherein:

FIGS. 1A to 1D are cross-sectional views illustrating a conventional method for forming a shallow trench isolation;

FIG. 2 is a graph showing a height of a stepped oxide film relative to a polishing time, after polishing the oxide film using a slurry that selectively removes the oxide film, according to the present invention;

FIGS. 3A and 3B are schematic cross-sectional views illustrating profiles of a stepped oxide film according the present invention;

FIGS. 4A to 4F are cross-sectional views illustrating a method for forming a shallow trench isolation according to a first embodiment of the present invention;

FIG. 5 is a schematic cross-sectional view illustrating a process for etching an oxide film with an etchant according to the first embodiment of the present invention;

FIGS. 6A to 6E are cross-sectional views illustrating a method for forming filling oxide films according to a second embodiment of the present invention; and

FIG. 7 is a graph showing heights of stepped films to be polished relative to a polishing time when polishing processes are performed using slurries including cerium oxide, according to the conventional polishing method and according to the present invention.

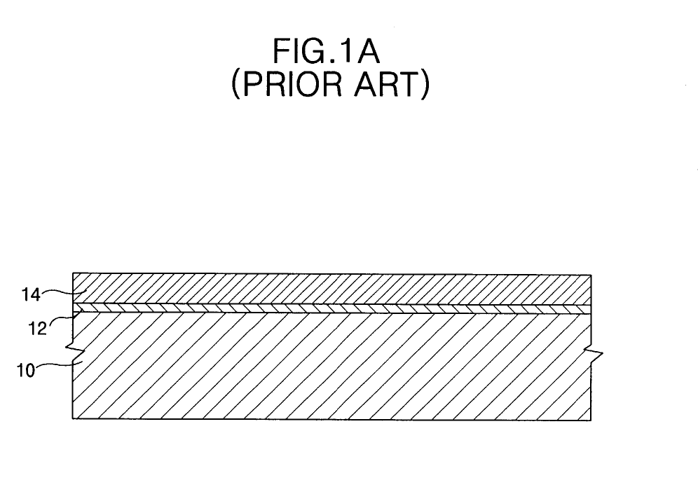

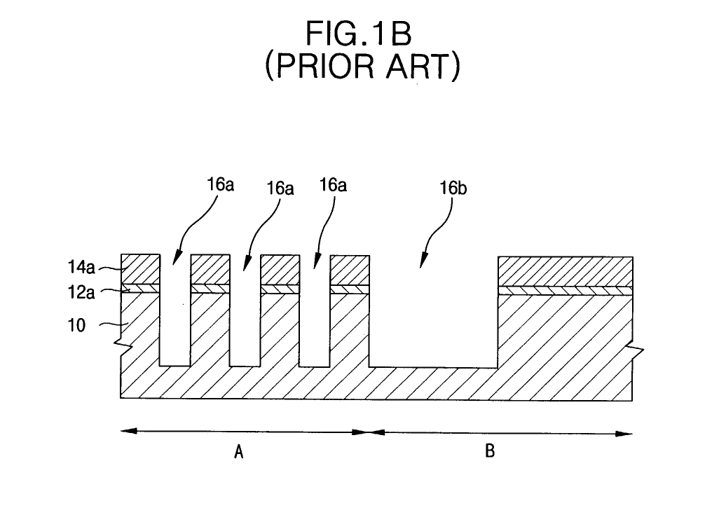

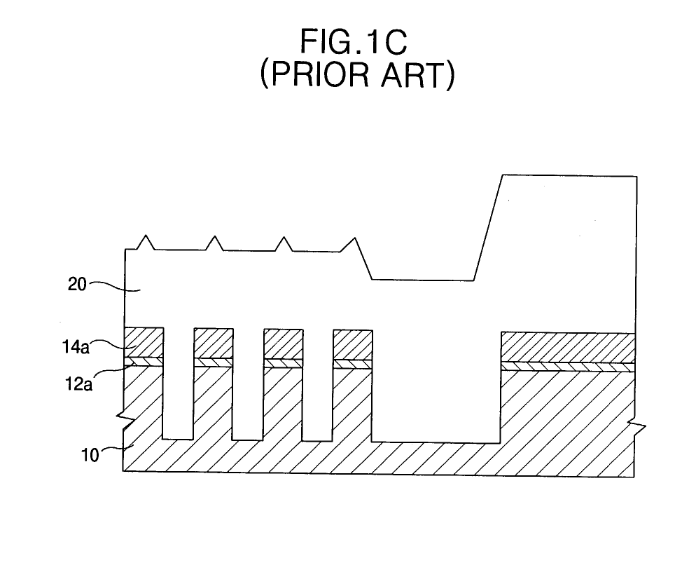

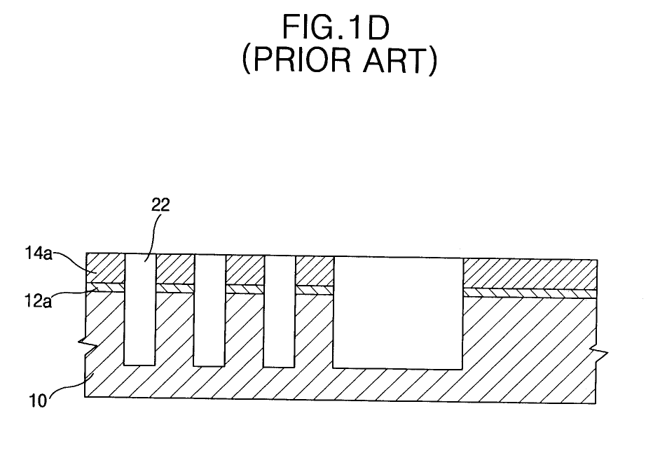

### DESCRIPTION OF THE PREFERRED EMBODIMENTS

Hereinafter, preferred embodiments of the present invention will be described in detail with reference to the accompanying drawings. In the following drawings, like reference numerals identify similar or identical elements.

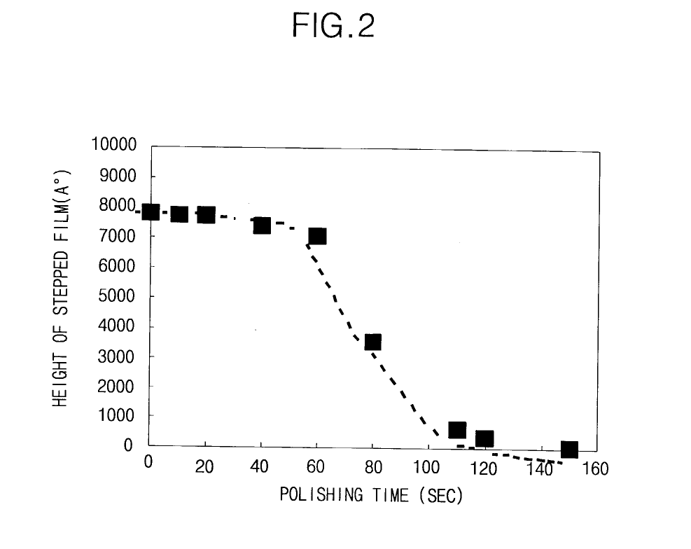

FIG. 2 is a graph showing the height of a stepped oxide film relative to a polishing time, during polishing of the oxide film using a slurry that selectively removes the oxide film, according to the present invention. In FIG. 2, the height of the stepped portion of the oxide film is approximately 8,000 Å before polishing, and the oxide film is polished until the stepped portion has disappeared from the oxide film.

As shown in FIG. 2, the height of the stepped portion of the oxide film is reduced by approximately 1,000 Å after about 60 seconds from the start of a chemical-mechanical polishing (CMP) process. Then, the height of the stepped portion is reduced by approximately 7,000 Å after about 60 to 120 seconds from the start of the mechanical polishing (CMP) process. When a slurry that selectively removes the oxide film is used during the CMP process, the oxide film cannot be easily polished during the initial step of the CMP process, as compared with successive steps of the CMP process over an identical amount of time.

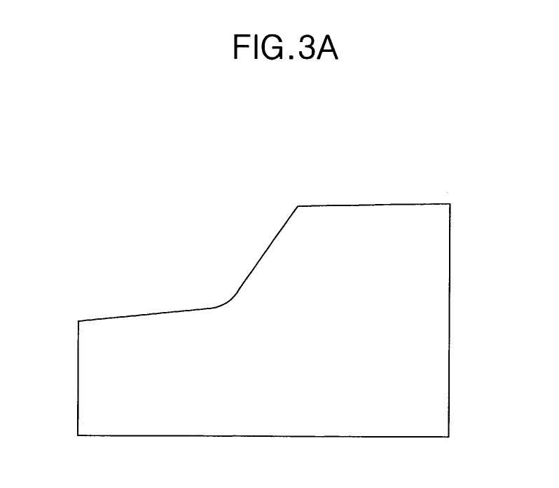

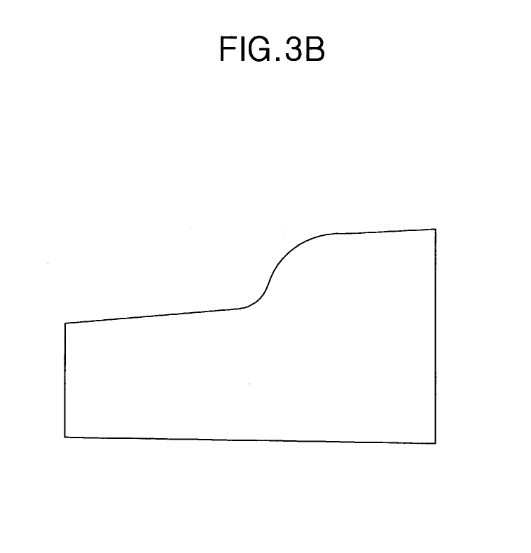

FIG. 3A is a schematic cross-sectional view illustrating the profile of a stepped oxide film before the CMP process, and FIG. 3B is a schematic cross-sectional view showing the profile of the stepped oxide film in which the oxide film is rapidly removed during the CMP process. Referring to FIGS. 3A and 3B, the edge portion of the stepped oxide film has a very sharp shape in FIG. 3A, while the edge portion of the stepped oxide film has a round shape and the slope of the stepped oxide film becomes smooth in FIG. 3B. In view of the profile difference between the oxide films in FIGS. 3A and 3B during the CMP process, it is noted that the polishing rate of the oxide film is slow before the edge of the stepped oxide film has attained the round shape, and the polishing rate of the oxide film becomes fast after the edge of the stepped oxide film has attained the round shape. Therefore, when the edge of the stepped oxide film is processed to have the round shape before polishing the oxide film, the oxide film can be more rapidly polished.

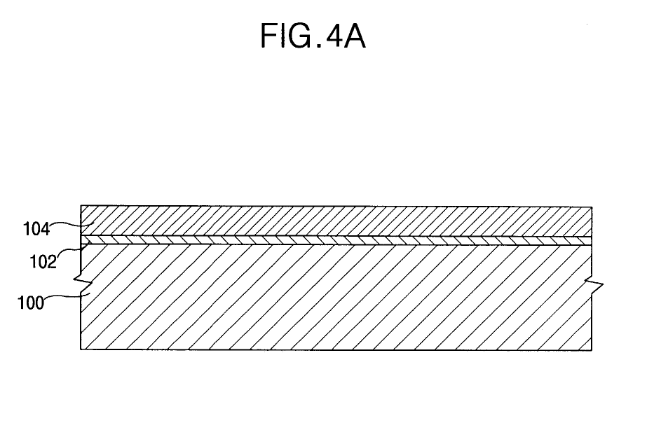

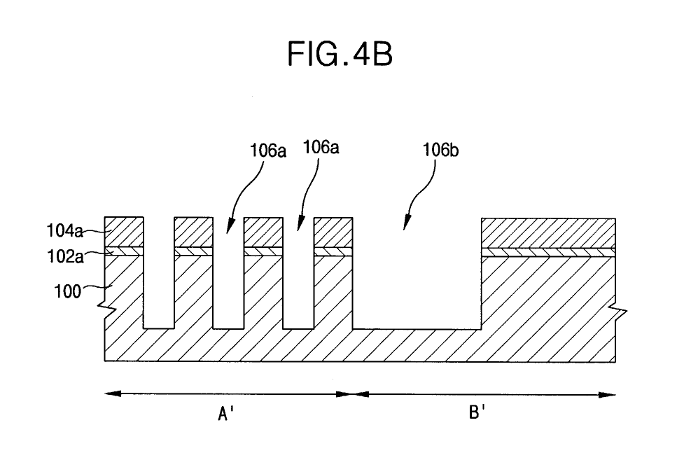

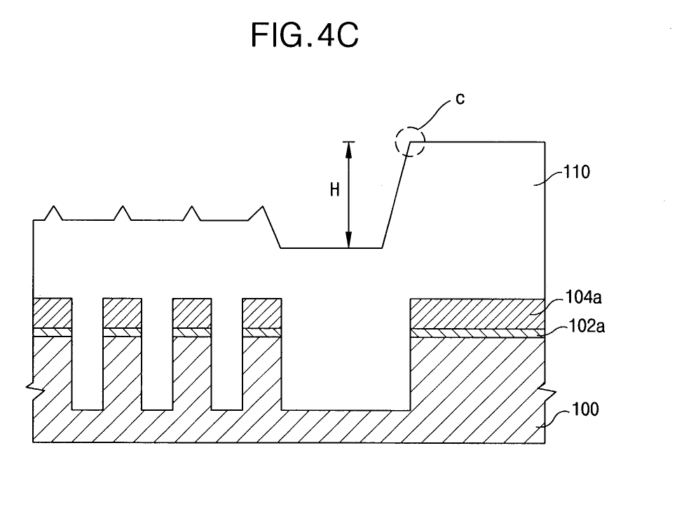

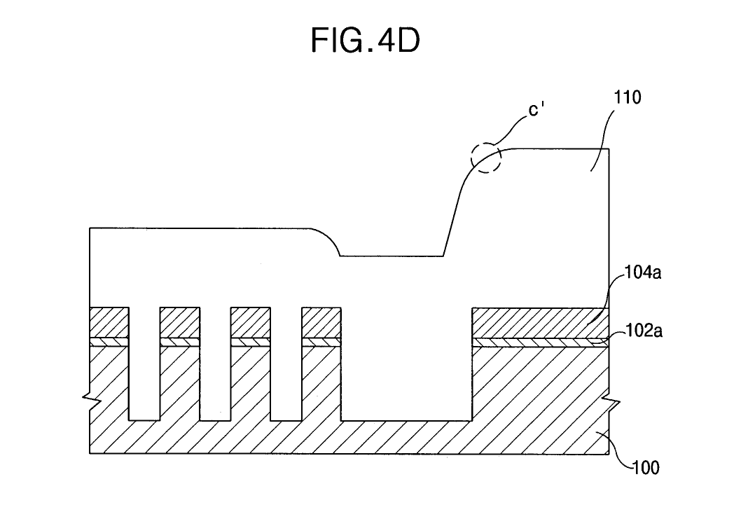

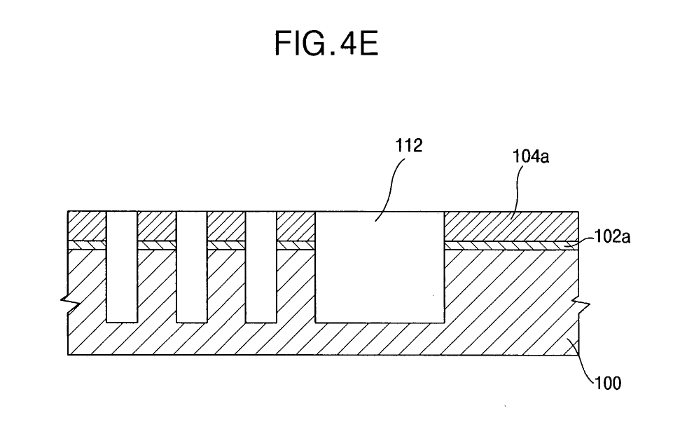

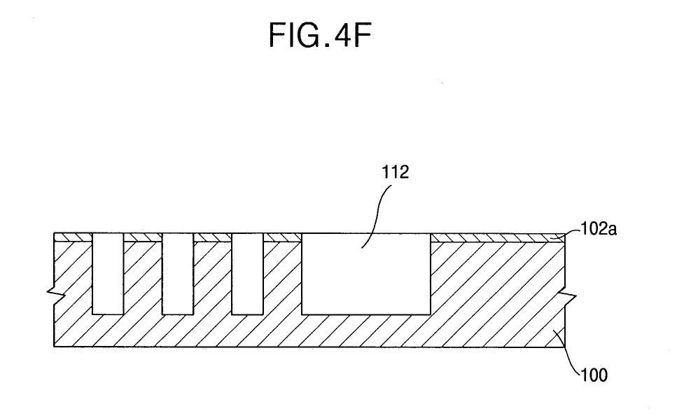

FIGS. 4A to 4F are cross-sectional views illustrating a method for forming a shallow trench isolation according to a first embodiment of the present invention. Referring to FIG. 4A, a pad oxide film 102 is formed on a semiconductor substrate 100 through a thermal oxidation process, or is formed in an open atmosphere as a native oxide. The pad oxide 102 has a thickness of approximately 30 to 200 Å.

Then, a polishing stop layer 104 having a thickness of approximately 100 to 2,000 Å is formed on the pad oxide film 102. The polishing stop layer 104 includes a material that can be selectivity removed relative to an oxide film for filling a gap during a subsequent chemical-mechanical polishing process. The removing selectivity between the polishing stop later 104 and the oxide film for filling the gap should be greater than about 1:5. The polishing stop layer 104 also serves as a hard mask during the formation of a trench. For example, the polishing stop layer 104 includes a nitride film formed by a low pressure chemical vapor deposition (LPCVD) process to have the thickness of approximately 200 to 2,000 Å.

Subsequently, a silicon oxy-nitride is deposited on the polishing stop layer 104 by an LPCVD process, so that an anti-reflection layer (not shown) having a thickness of approximately 200 to 800 Å is formed on the polishing stop later 104. Then, a photolithography process is performed to define an active region and a field region of the substrate 100. The anti-reflection layer prevents scattered reflection of light during the photolithography process, and the anti-reflection layer is removed during the formation of the trench.

Referring to FIG. 4B, polishing stop layer patterns 104a and pad oxide film patterns 102a are formed in the field region of the substrate 100 defined through the photolithography process after etching of the polishing stop layer 104 and the pad oxide film 102. Then, trenches 106a and 106b are formed in exposed portions of the substrate 100 between the polishing stop layer patterns 104a by etching the substrate 100 to a depth of approximately 2,000 to 6,000 Å. At that time, the anti-reflection layer is removed from the substrate 100.

In general, the trenches 106a formed in a cell region (A′) of the substrate 100 have narrow widths, and the trenches 106b formed in a peripheral region (B′) of the substrate 100 have relatively wide widths. In addition, the trenches 106a formed in the cell region (A′) have narrow intervals therebetween, and the trenches 106b formed in the peripheral region (B′) have relatively wide intervals therebetween.

Referring to FIG. 4C, an oxide film 110 having good properties for filling a gap is formed on the substrate 100 to cover the trenches 106a and 106b by a high density plasma (HDP) chemical vapor deposition process or a plasma enhanced chemical vapor deposition (PECVD) process. The oxide film 110 may include a high density plasma oxide film formed using high density plasma generated from a plasma source of SiH₄ gas, O₂ gas, and Ar gas. Additionally, the oxide film 110 can include a plasma enhanced tetraethylorthosilicate (TEOS) film formed using plasma generated from the source of Si(OC₂H₅)₄.

Because the oxide film 110 should fill the trenches 106a and 106b, the thickness of the oxide film 110 is at least greater than the depths of the trenches 106a and 106b. The thickness of the oxide film 110 may be greater than the depths of the trenches 106a and 106b by approximately 1,000 to 5,000 Å, since a process margin is required in order to prevent dishing of the oxide film 110 filled in the trenches 106a and 106b during subsequent processes.

When the oxide film 110 is formed on the substrate 100, stepped portions of the oxide film 110 are generated at portions of the substrate 100 where the trenches 106a and 106b are positioned and at portions of the substrate 100 where the trenches 106a and 106b are not formed, as shown in FIG. 4C. Also, heights of the stepped portions of the oxide film 110 are varied in accordance with the widths of the trenches 106a and 106b. In detail, the portions of the oxide film 110 filling the trench 106b having the relatively wide widths in the peripheral region (B′) are less protruded than the portions of the oxide film 110 filling the trenches 106a having narrow widths in the cell region (A′). Furthermore, the portion of the oxide film 110 formed on a portion of the peripheral region (B′) where the trench 106b is not positioned is more protruded than any other portions of the oxide film 110. Thus, the height of the stepped portion (H) of the oxide film 110 has a largest value at the portion of the peripheral region (B′) between the trench 106b and the portion where the trench 106b is not formed.

The height of the stepped portion (H) of the oxide film 110 is similar to the depths of the trenches 106a and 106b. In the peripheral region (B′), the edge (C) of the stepped portion of the oxide film 110, generated due to the height of the stepped portion (H) of the oxide film 110 between the trenches 106a and 106b and the portion where the trenches 106a and 106b are not formed thereon, has a very sharp shape, and the slope of the stepped portion of the oxide film 110 has a steep slope.

Referring to FIG. 4D, the edge (C′) of the stepped portion of the oxide film 110 is treated to have a round shape. The edge (C′) of the stepped portion of the oxide film 110 should be rounded such that the slurry used in the subsequent polishing process can go over the edge (C′) to be provided onto the highly stepped portion of the oxide film 110. Particularly, the oxide film 110 is isotropically etched with an etchant for etching oxide. In this case, the etchant is simultaneously employed on the whole surface of the oxide film 110 to polish the oxide film 110.

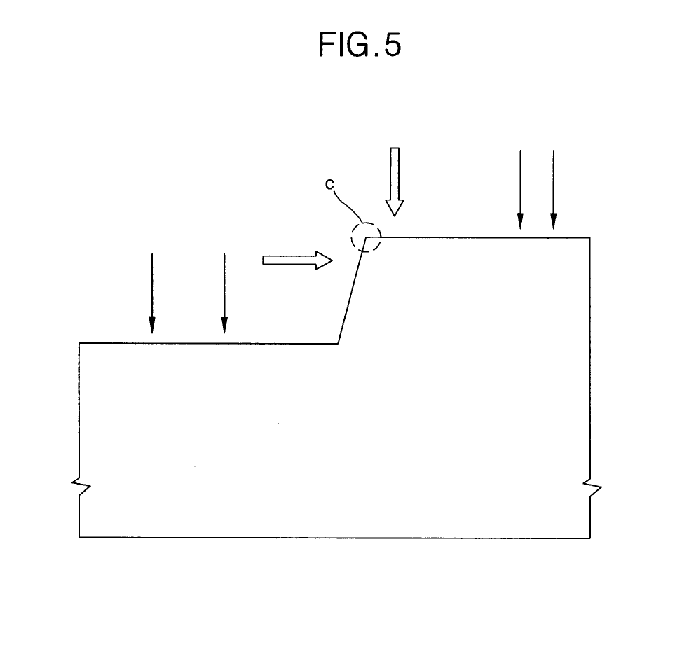

FIG. 5 is a schematic cross-sectional view illustrating the process for etching the oxide film by employing an etchant onto the oxide film. Referring to FIG. 5, the edge (C) of the stepped portion of the oxide film 110 is more rapidly etched than other portions of the oxide film 110 because the edge (C) of the stepped portion is etched from the left and the right sides thereof by the etchant simultaneously employed on the whole surface of the oxide film 110, which includes the portion where the trenches 106a and 106b are formed and the portion where the trenches 106a and 106b are not positioned. Hence, the edge (C) of the stepped portion of the oxide film 110 can have a sufficiently round shape when the oxide film 110 is etched to the depth of approximately 200 to 3,000 Å. At that time, the oxide film 110 is isotropically etched such that the portions of the oxide film 110 filling the trenches 106a and 106b should have heights higher than those of the polishing stop layer patterns 104a. The oxide film 110 should be etched to have a thickness of approximately 100 to 3,000 Å from the surfaces of the polishing stop layer patterns 104a, because a process margin should be ensured in order to prevent dishing of the field oxide film filling the trenches 106a and 106b during the subsequent chemical-mechanical polishing process. For example, a buffered hydrogen fluoride solution can be used as the etchant for the isotropic etching of the oxide film 110.

Referring to FIG. 4E, the oxide film 110 having the round edge (C′) is polished by the chemical-mechanical polishing process until the polishing stop layer pattern 104a is exposed, thereby forming field oxide films 112 having even surfaces in the trenches 106a and 106b. In the chemical-mechanical polishing process, the slurry for selectively polishing the oxide film 110 is employed. In detail, the slurry can selectively remove the oxide film 110 relative to the polishing stop layer pattern 104a with a removing ratio of more than about 5:1. For example, the slurry can include cerium dioxide (CeO₂). The slurry including cerium dioxide is directly combined with dangling bonds in the surface of the oxide film 110, so that the oxide film 110 is chemically polished. That is, the slurry including cerium oxide makes direct contact with the surface of the oxide film 110 in order to chemically polish the oxide film 110.

When the chemical-mechanical polishing process is executed with the slurry including cerium dioxide, a polishing uniformity difference of the process may seriously occur according to the condition of the slurry making contact with the surface of the oxide film 110 to be polished, as compared with other slurries including silicon oxide (SiO₂) used during a chemical-mechanical polishing process. For instance, a slurry including silicon oxide is reacted with the oxide film 110 to form a hydrated layer such that the slurry including silicon oxide chemically polishes the oxide film. Thus, when the chemical-mechanical polishing process is performed using the slurry including silicon oxide, the process has a polishing uniformity difference, caused by the contacting condition between the slurry and the oxide film, relatively lower than that of the process using the slurry including cerium dioxide. However, the slurry including silicon oxide cannot selectively remove the oxide film 110 relative to the polishing stop layer pattern 104a. Therefore, It is difficult to use the slurry including silicon oxide in the CMP process.

When the film to be polished has a highly stepped portion wherein the stepped portion includes the edge having a sharp shape and a steep slope, the slurry on the portions of the film relatively lower than the highly stepped portion can hardly move toward the highly stepped portion of the film during the initial step of a polishing process. Hence, the polishing rate of the highly stepped portion is very slow because the slurry rarely exists on the highly stepped portion of the film to be polished. In case that the polishing process is somewhat progressed to reduce the height and the slope of the highly stepped portion, the slurry can move onto the highly stepped portion of the film to be polished, thereby greatly increasing the polishing rate of the film to be polished.

However, in the present embodiment, the slurry can sufficiently move onto the highly stepped portion of the oxide film 110 because the edge (C′) of the oxide film 110 is previously processed to have a round shape. Therefore, the oxide film 110 including the stepped portion can be rapidly polished from the initial step of the polishing process, so the field oxide film 112 can be rapidly formed in the trenches 106a and 106b, because the polishing process is performed much faster than the conventional polishing process.

Referring to FIG. 4F, the polishing stop patterns 104a are removed from the substrate 100.

As described above, the oxide film 110 can be rapidly polished so that the time of the polishing process decreases. In addition, because each substrate including an oxide film is polished through a separate polishing process, the entire time of the polishing processes can be greatly reduced, thereby improving yield of the semiconductor manufacturing process.

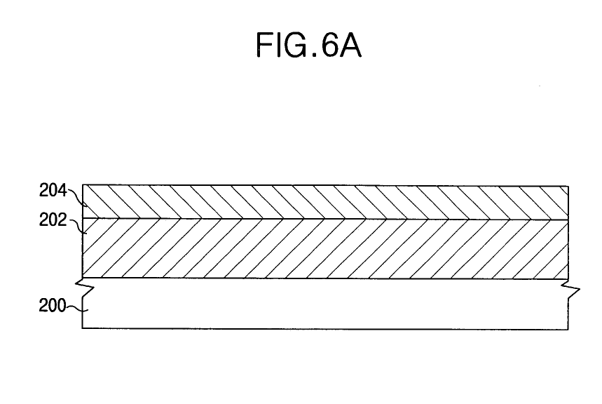

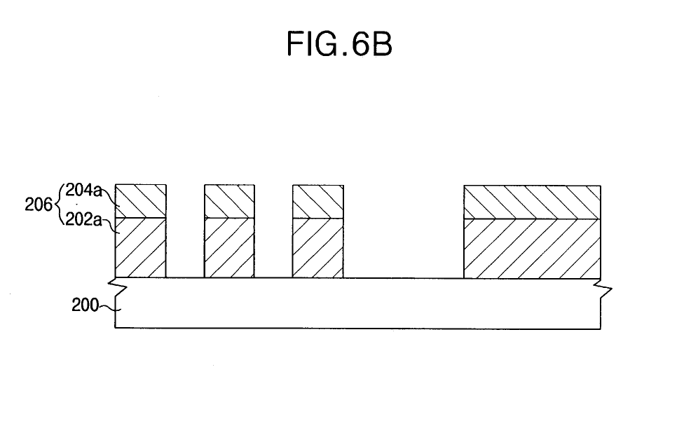

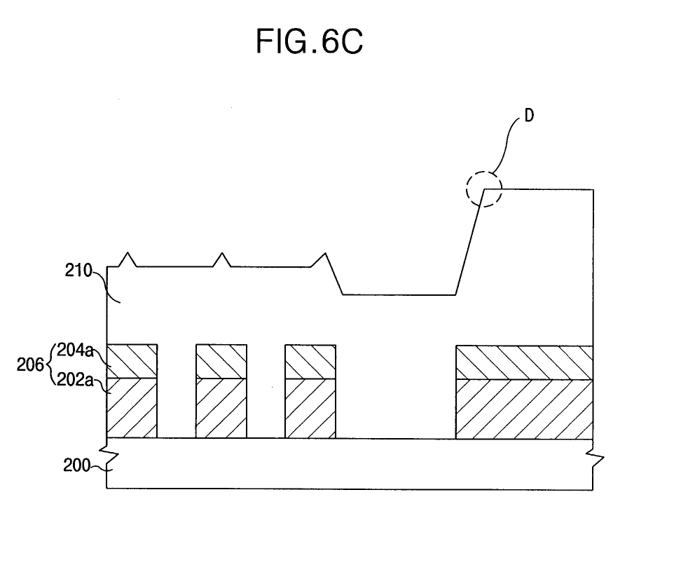

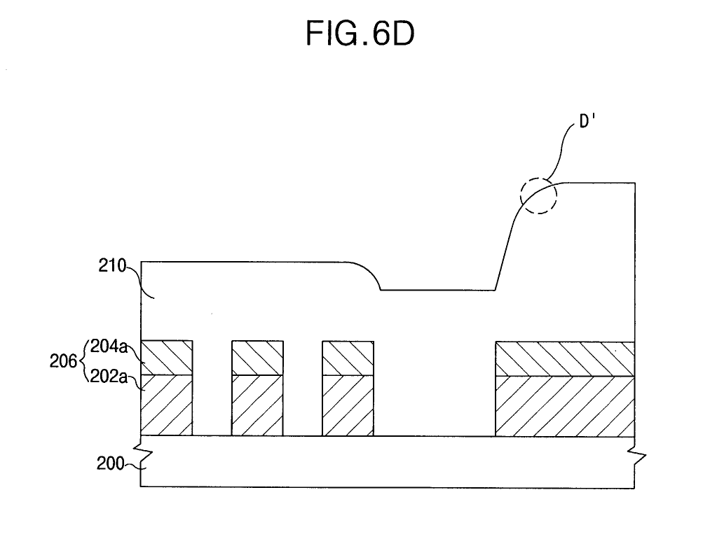

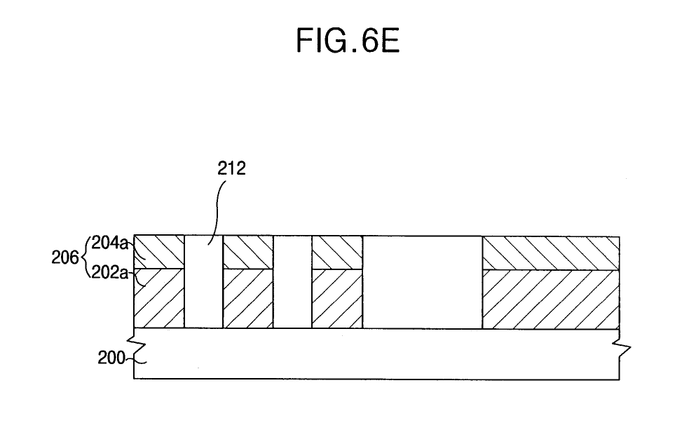

FIGS. 6A to 6E are cross-sectional views illustrating a method for forming filling oxide films according to a second embodiment of the present invention. Referring to FIG. 6A, a first film 202 including a polysilicon film or a metal film is formed on a semiconductor substrate 200. Then, a polishing stop layer 204 is formed on the first film 202 using a material that is selectively removable relative to a gap filling oxide film subsequently formed. The polishing stop layer 204 has a removing selectivity of no less than about 1:5 relative to the gap filling oxide film. For example, the polishing stop layer 204 includes a nitride film having a thickness of approximately 200 to 2,000 Å formed by an LPCVD process.

Referring to FIG. 6B, portions of the polishing stop layer 204 and the first film 202 are successively etched to form structures 206 including polishing stop layer patterns 204a and first film patterns 202a, respectively. The intervals between the structures 206 are irregular in accordance with the regions of the substrate 200. That is, the interval between the structures 206 is relatively narrow in a cell region of the substrate 200, and the interval between the structures 206 is relatively wide in a peripheral region of the substrate 200. In addition, the widths of the structures 206 are varied according to the regions of the substrate 200.

Referring to FIG. 6C, an oxide film 210 is formed on the substrate 200 to cover the structures 206 through an HDP chemical vapor deposition process or a PECVD process. The oxide film 210 includes a material having good gap filling characteristics to sufficiently fill up a space between the structures 206. The oxide film 210 may include an HDP oxide film formed using a high density plasma generated from a plasma source of a SiH₄ gas, an O₂ gas and an Ar gas. Also, the oxide film 210 can include a PE-TEOS film formed using a plasma generated from a source of Si(OC₂H₅)₄.

Because the oxide film 210 fills up the space between the structures 206, the oxide film 210 has a height at least higher than that of the structures 206. The oxide film 210 is protruded from the structures 206 by approximately 1,000 to 5,000 Å. Thus, a processing margin of a subsequent process can be ensured in order to prevent dishing of the oxide film 210 filled between the structures 206 during subsequent processes.

When the oxide film 210 is formed on the substrate 200, stepped portions of the oxide film 210 are generated because the portions of the oxide film 210 on the structures 206 are protruded from the portions of the oxide film 210 between the structures 206, as shown in FIG. 6C. Particularly, the highest stepped portion of the oxide film 210 is generated between the portion of the oxide film 210 filling between the structures 206 disposed by the relatively wide interval, and the portion of the oxide film 210 on the structure 206 having the relatively wide width. In this case, the edge (D) of the highest stepped portion of the oxide film 210 has a very sharp shape, and the slope of the highest stepped portion of the oxide film 210 has a steep slope.

Referring to FIG. 6D, the edge (D′) of the highest stepped portion of the oxide film 210 is treated to have a round shape. The edge (D′) of the highest stepped portion of the oxide film 210 is preferably rounded so that the slurry used in the subsequent polishing process can go over the edge (D′) to be provided onto the highest stepped portion of the oxide film 210. In detail, the oxide film 210 is isotropically etched with an etchant for etching oxide. At that time, the etchant is simultaneously employed on the whole surface of the oxide film 210. During the isotropic etching process, the oxide film 210 is isotropically etched such that the portions of the oxide film 210 filling up the space between the structures 206 has height higher than those of the polishing stop layer patterns 204a. The oxide film 210 is etched such that the oxide film 210 is protruded from the surfaces of the polishing stop layer patterns 204a by a thickness of approximately 100 to 3,000 Å.

Referring to FIG. 6E, the oxide film 210 having the round edge (D′) is polished by a chemical-mechanical polishing process until the polishing stop layer pattern 204a is exposed, thereby forming field oxide films 212 having even surfaces between the structures 206. In the chemical-mechanical polishing process, the slurry for selectively polishing the oxide film 210 is employed. Particularly, the slurry can selectively remove the oxide film 210 relative to the polishing stop layer pattern 204a by a removing ratio of more than about 5:1. For example, the slurry can include cerium dioxide (CeO₂). The slurry including cerium oxide is directly combined with dangling bonds in the surface of the oxide film 210 so that the oxide film 210 is chemically polished.

The slurry can sufficiently move onto the highest stepped portion of the oxide film 210 because the edge (D′) of the oxide film 210 is previously processed to have the round shape. Hence, the oxide film 210 including the stepped portions can be rapidly polished from the initial step of the polishing process, so that the field 212 can be rapidly formed in the structures 206 because the polishing performed much faster than the conventional polishing process.

Comparative Experiment 1 Illustrating the Removing Rate of the Polishing Process

Table 1 shows the heights of the stepped films to be polished when polishing processes are performed using a slurry including cerium oxide, according to a conventional method and according to the present invention.

Each trench was formed in each substrate to have the depth of approximately 2,800 Å, and each oxide film filling each trench was formed to have a thickness of approximately 5,500 Å through an HDP chemical vapor deposition process. The oxide films on the substrates were isotropically etched by approximately 250 Å, 300 Å and 500 Å, respectively, and then the oxide films were polished. In this case, one oxide film on a substrate was not etched. As shown in Table 1, the polishing rates of the isotropically etched oxide films on the substrates were faster than that of the oxide film that was not etched.

TABLE 1

| | the thickness of the oxide film remaining on a substrate (Å) | | | |
|---|---|---|---|---|
| polishing | | after etching | after etching | after etching |
| time (SEC) | after no etching | by 250Å | by 300Å | by 1,000Å |
| 0 | 5567 | 5360 | 4853 | 4210 |
| 15 | 5475 | 5239 | 4846 | 4176 |
| 30 | 5360 | 4953 | 4598 | 3800 |
| 40 | 5170 | 3614 | 4242 | 3350 |
| 50 | 4760 | 2539 | 3626 | 2380 |
| 60 | 3707 | 438 | 2430 | 1110 |
| 80 | 938 | 28 | 193 | 0 |

Comparative Experiment 2 Illustrating the Removing Rate of the Polishing Process

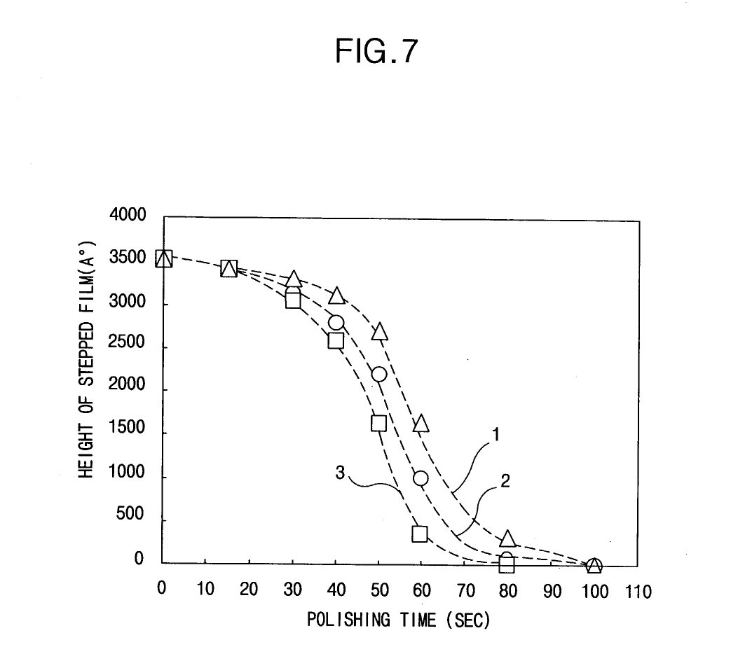

FIG. 7 is a graph showing the heights of the stepped films to be polished relative to the polishing time when polishing processes are performed using the slurries including cerium dioxide, according to a conventional polishing method and according to the present invention.

Oxide films were formed on substrates to have a stepped thickness of approximately 3,500 Å, and then the oxide films were isotropically etched by approximately 500 Å and 1,000 Å, respectively. On the other hand, one oxide film was not etched. Subsequently, all the oxide films were polished under identical polishing conditions.

In FIG. 7, the height variation of the stepped oxide film when the oxide film is not etched is denoted by reference numeral 1, and the height variation of the stepped oxide film when the oxide film is etched by approximately 500 Å is denoted by reference numeral 2. Additionally, when the oxide film is etched by approximately 1,000 Å, the height variation of the stepped oxide film is denoted by reference numerical 3. Referring to FIG. 7, when the oxide films are polished after the oxide films were isotropically etched by approximately 500 Å and 1,000 Å, respectively, the polishing rates of the oxide films were faster than the polishing rate of the oxide film that was not etched.

According to this embodiment of the present invention, the edge of the stepped portion of the oxide film 210 is treated to have a round shape before the polishing process. Thus, the polishing rate of the oxide film 210 can be enhanced and the throughput of the semiconductor manufacturing process can be improved.

As it is described above, according to the present invention, the edge of the highest stepped portion of the film to be polished is treated to have a round shape before the chemical-mechanical polishing process is executed. Therefore, the film can be rapidly polished because the slurry can be sufficiently employed onto the highest stepped portion of the film from the initial step of the polishing process. As a result, the time of the polishing process greatly decreases and the productivity of the semiconductor manufacturing process can be improved.

Although the preferred embodiments of the present invention have been described, it is understood that the present invention should not be limited to these preferred embodiments, but various changes and modifications can be made by one skilled in the art within the spirit and scope of the present invention as hereinafter claimed.

What is claimed is:

1. A method for forming a filling film comprising:
providing a substrate having stepped portions;
forming a film on the substrate to cover the stepped portions;
processing an edge of a stepped portion of the film to have a round shape, the edge of the stepped portion of the film being formed in accordance with the stepped portions of the substrate; and
chemical-mechanically polishing the film including the round shaped edge to have an even surface.

2. The method for forming a filling film of claim 1, wherein the film is formed by a high density plasma chemical vapor deposition process or a plasma enhanced chemical vapor deposition process.

3. The method for forming a filling film of claim 1, wherein said processing an edge of the film comprises isotropically etching the film to a predetermined depth.

4. The method for forming a filling film of claim 1, further comprising forming a polishing stop layer on the substrate before said forming a film on the substrate.

5. The method for forming a filling film of claim 4, wherein said processing an edge of the film comprises isotropically etching the film to have a thickness of approximately 100 to 3,000 Å from the polishing stop layer.

6. The method for forming a filling film of claim 1, wherein said chemical-mechanically polishing the film comprises using a slurry that directly combines with dangling bonds in a surface of the film to remove the film.

7. The method for forming a filling film of claim 1, wherein said chemical-mechanically polishing the film comprises using a slurry that selectively removes the film.

8. The method for forming a filling film of claim 4, wherein the polishing stop layer comprises a nitride film.

9. The method for forming a filling film of claim 1, wherein the film comprises an oxide film.

10. A method for forming a trench isolation comprising:
forming a polishing stop layer on a substrate;
successively etching portions of the polishing stop layer and the substrate to form trenches in the substrate;
forming an oxide film to cover the trenches;
processing an edge of a stepped portion of the oxide film to have a round shape, the edge of the stepped portion of the oxide film being formed in accordance with formations of the trenches; and
chemical-mechanically polishing the oxide film including the round shaped edge to expose the polishing stop layer.

11. The method for forming a trench isolation of claim 10, wherein the trenches have different widths depending on regions of the substrate.

12. The method for forming a trench isolation of claim 10, wherein intervals between the trenches are different depending on regions of the substrate.

13. The method for forming a trench isolation of claim 10, wherein the oxide film is formed by a high density plasma chemical vapor deposition process or a plasma enhanced chemical vapor deposition.

14. The method for forming a trench isolation of claim 10, wherein the oxide film has a height higher than depths of the trenches by approximately 1,000 to 5,000 Å.

15. The method for forming a trench isolation of claim 10, wherein said processing an edge of the oxide film comprises isotropically etching the oxide film to a predetermined depth.

16. The method for forming a trench isolation of claim 15, wherein said isotropically etching the oxide film is performed so that the oxide film that fills the trenches is at least higher than the polishing stop layer.

17. The method for forming a trench isolation of claim 16, wherein said isotropically etching the oxide film is performed so that the oxide film has a thickness of at least approximately 100 to 3,000 Å from the polishing stop layer.

18. The method for forming a trench isolation of claim 10, wherein said chemical-mechanically polishing the oxide film comprises using a slurry that directly combines with dangling bonds in a surface of the oxide film to remove the oxide film.

19. The method for forming a trench isolation of claim 10, wherein said chemical-mechanically polishing the oxide film comprises using a slurry that selectively removes the oxide film.

20. The method for forming a trench isolation of claim 19, wherein the slurry selectively removes the oxide film relative to the polishing stop layer with a removing ratio of about 5:1.

21. The method for forming a trench isolation of claim 10, wherein the polishing stop layer comprises a nitride film.

22. The method for forming a trench isolation of claim 10, further comprising forming an anti-reflection layer on the polishing stop layer.

23. The method for forming a trench isolation of claim 10, further comprising removing the exposed polishing stop layer after said chemical-mechanically polishing.
